(19) United States
(12) Patent Application Publication
(10) Pub. No.: US 2010/0053900 A1
(43) Pub. Date: Mar. 4, 2010

(54) HEAT DISSIPATION STRUCTURE AND VEHICULAR INVERTER

(75) Inventor: Mari ONO, Toyota-shi (JP)

Correspondence Address: SUGHRUE MION, PLLC, 2100 PENNSYLVANIA AVENUE, N.W., SUITE 800, WASHINGTON, DC, 20037, US

(73) Assignee: TOYOTA JIDOSHA KABUSHIKI KAISHA, Toyota-shi (JP)

(21) Appl. No.: 12/537,293

(22) Filed: Aug. 7, 2009

(30) Foreign Application Priority Data
Aug. 26, 2008 (JP) 2008-217071

(51) Int. Cl. H05K 7/20; F28F 7/00; F28F 21/00

(52) U.S. Cl. 361/704; 165/185; 363/141

(57) ABSTRACT

A heat dissipation structure is equipped with a heating element; a substrate, on which the heating element is provided; and a heat dissipation member that is in contact with the substrate via thermally conductive grease. The substrate and the heat dissipation member have contact surfaces that are in contact with each other, and at least one of the contact surfaces has a first contact region on which the thermally conductive grease is disposed, and a second contact region that surrounds the first contact region. A surface roughness of the second contact region is lower than a surface roughness of the first contact region.

### INCORPORATION BY REFERENCE

The disclosure of Japanese Patent Application No. 2008-217071 filed on Aug. 26, 2008 including the specification, drawings and abstract is incorporated herein by reference in its entirety.

### BACKGROUND OF THE INVENTION

1. Field of the Invention

The invention relates to a heat dissipation structure for dissipating heat from a heating element, and more particularly, to a heat dissipation structure suited to dissipate heat by taking advantage of grease.

2. Description of the Related Art

A vehicular inverter or the like mounted with electronic components adopts a heat dissipation structure. For example, a power control unit for the vehicular inverter is composed of an inverter portion and a boost converter portion. As shown in FIG. 5, a boost converter has disposed in a case (substrate) 70 thereof a boost intelligent power module (boost IPM) 11 and a reactor 12. The boost IPM 11 and the reactor 12 are heating elements that generate heat when the inverter is in use. Therefore, with a view to radiating this generated heat, a cooler (heat dissipation member) 80 including a heat sink is disposed in the boost converter in contact with the case 70 via thermally conductive grease (heat dissipation grease) G.

If the described heat dissipation structure is adopted, the thermally conductive grease G between the case 70 and the cooler 80 may flow as heat is generated by the heating elements 11 and 12. In particular, if the respective contact surfaces of the case 70 and the cooler 80, which are in contact with each other, are inclined with respect to the ground or if the case 70 or the cooler 80 repeatedly expands and contracts in an environment in which heat generation and cooling are repeated as described above, then the thermally conductive grease G is likely to flow, if the surfaces of the case 70 and the cooler 80 on which the thermally conductive grease G is disposed have a low surface roughness. Then, due to the flow of this thermally conductive grease G, an air may intrude between the case 70 and the cooler 80, which degrades heat dissipation.

In consideration of this background, there is proposed, for example, a heat dissipation structure in which thermally conductive grease is disposed on irregularity formed contact surfaces of a case and a cooler (e.g., see Japanese Patent Application Publication No. 2006-49501 (JP-A-2006-49501)). Because of the irregularity of the surfaces on which the thermally conductive grease is disposed, the heat dissipation structure can restrain the thermally conductive grease from flowing.

Grease, such as thermally conductive grease or the like, is basically composed of a thickening agent (filler), a base oil (oil), and an additive. When the heat dissipation structure described in Japanese Patent Application Publication No. 2006-49501 (JP-A-2006-49501) is adopted, although the thermally conductive grease itself is unlikely to flow, the irregularity of the surfaces may separate only an oil component of the thermally conductive grease from the grease, and consequently results in a deterioration in heat dissipation performance of the heat dissipation structure.

This is considered to be ascribable to the following fact. That is, as a result of an increase in the degree of surface roughness of the contact surfaces of the cooler and the case, there is created a slight gap therebetween. Due to this gap, only the oil component of the thermally conductive grease diffusely flows through a capillary phenomenon.

### SUMMARY OF THE INVENTION

The invention provides a heat dissipation structure that suppresses deterioration in heat dissipation performance not only by restraining thermally conductive grease used in the heat dissipation structure from flowing but also by restraining an oil component as one of base components of the thermally conductive grease from flowing out.

A first aspect of the invention relates to a heat dissipation structure. The heat dissipation structure includes a heating element, a substrate on which the heating element is provided, a thermally conductive grease that is provided in a manner such that the substrate is disposed between the heating element and the thermally conductive grease, and a heat dissipation member that is in contact with the substrate via the thermally conductive grease. In this heat dissipation structure, the substrate and the heat dissipation member have contact surfaces that are in contact with each other, and at least one of the contact surfaces has a first contact region on which the thermally conductive grease is disposed, and a second contact region that surrounds the first contact region. A surface roughness of the second contact region is lower than a surface roughness of the first contact region.

Because the surface roughness of the second contact region on which the thermally conductive grease is disposed is lower than the surface roughness of the first contact region, the heat disspation structure according to the first aspect of the invention can restrain the thermally conductive grease on the first contact region from flowing. Furthermore, in this heat dissipation structure, the second contact region is so provided as to surround the first contact region. Therefore, the oil component of the thermally conductive grease disposed on the first contact region seldom flows to the second contact region through the capillary phenomenon. As a result, in this heat dissipation structure, an air layer is unlikely to be formed through the flow of the thermally conductive grease in the first contact region, and the oil component of the thermally conductive grease is unlikely to flow out from the first contact region toward the second contact region. Thus, in this heat dissipation structure, the dissipation of heat from the heating element provided on the substrate is restrained from deteriorating, and this heat is dissipated from the heat dissipation member via the thermally conductive grease.

“The thermally conductive grease” may be a so-called heat dissipation grease. Suitable thermally conductive greases include, for example, silicone grease. However, the thermally conductive grease is not limited to silicone grease in particular. Any grease with a composition that allows easy heat conduction (with excellent heat dissipation) may be used as the thermally conductive grease.

Further, in the heat dissipation structure according to the first aspect of the invention, heat dissipation may be ensured by making the surface roughness of the first contact region different from the surface roughness of the second contact region as described above. The surface roughness of the first contact region may have a centerline average roughness equal to or larger than 0.2 μm, and the surface roughness of the second contact region may have a centerline average roughness equal to or smaller than 0.05 μm.

In the heat dissipation structure according to the first aspect of the invention, as is apparent from a later-described exemplary embodiment of the invention, the thermally conductive grease can be restrained from flowing by making the centerline average roughness of the first contact region equal to or larger than 0.2 μm. By making the centerline average roughness of the second contact region equal to or smaller than 0.05 μm, the oil component of the thermally conductive grease can be restrained from flowing out from the first contact region to the second contact region through the capillary phenomenon. That is, in this heat dissipation structure, when the centerline average roughness of the first contact region is made equal to or smaller than 0.2 μm, the thermally conductive grease may be likely to flow. In this heat dissipation structure, when the centerline average roughness of the second contact region is made equal to or larger than 0.05 μm, the oil component of the thermally conductive grease may be likely to flow out.

Further, in the heat dissipation structure according to the first aspect of the invention, a plurality of pores may be formed in the first contact region in a thickness direction. Thus, the thermally conductive grease can be trapped in these pores, and the performance of heat dissipation can further be enhanced.

Further, a second aspect of the invention relates to a heat dissipation structure. This heat dissipation structure is equipped with a heating element, a substrate on which the heating element is provided, a thermally conductive grease that is provided in a manner such that the substrate is disposed between the heating element and the thermally conductive grease, and a heat dissipation member that is in contact with the substrate via thermally conductive grease. In this heat dissipation structure, the substrate and the heat dissipation member have contact surfaces that are in contact with each other, and at least one of the respective contact surfaces has a first contact region on which the thermally conductive grease is disposed and a second contact region that surrounds the first contact region. A plurality of pores, in which the thermally conductive grease is retained, is formed in the first contact region in a thickness direction.

In the heat dissipation structure according to the second aspect of the invention, the thermally conductive grease on the first contact region can be restrained from flowing by providing the plurality of the pores in the first contact region on which the thermally conductive grease is disposed. Furthermore, in this heat dissipation structure, the second contact region is so provided as to surround the first contact region. Therefore, as is the case with the foregoing first embodiment of the invention, the oil component of the thermally conductive grease disposed on the first contact region seldom flows to the second contact region through the capillary phenomenon. As a result, in this heat dissipation structure, an air layer is unlikely to be formed on the first contact region through the flow of the thermally conductive grease, and the oil component of the thermally conductive grease is unlikely to flow out. Thus, the performance of heat dissipation of this heat dissipation structure does not deteriorate. In this heat dissipation structure, heat of the heating element laid on the substrate is radiated from the heat dissipation member via the thermally conductive grease.

Further, in the heat dissipation structure according to the first aspect or the second aspect of the invention, the heating element may be provided on a face of the substrate which is opposite to a face of the substrate that contacts the heat dissipation member so that the heating element are at a position corresponding to the first contact region. By providing the heating element at this position, heat of the heating element can be more efficiently radiated from the heat dissipation member via the thermally conductive grease.

A third aspect of the invention relates to a vehicular inverter This vehicular inverter is equipped with one of the aforementioned heat dissipation structures. This vehicular inverter can favorably radiate heat of the heating element such as a reactor or the like, which is likely to generate heat. Therefore, the reliability of a vehicle can be enhanced.

According to the invention, a deterioration in heat dissipation may be suppressed not only by restraining the thermally conductive grease used in the heat dissipation structure from flowing but also by restraining the oil content as one of the base components of the thermally conductive grease from flowing out.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1A shows a cross-sectional view of the overall construction of a heat dissipation structure of a vehicular inverter according to the first embodiment of the invention as viewed from a direction perpendicular to a direction of contact between a cooler and a case including a heating element;

FIG. 1B shows a contact surface of the case shown in FIG. 1A;

FIG. 1C shows a contact surface of the cooler shown in FIG. 1A;

FIG. 2 shows an overall construction of a heat dissipation structure of a vehicular inverter according to the second embodiment of the invention;

FIG. 3A shows the results of a confirmation test for confirming the optimal surface roughness of first contact regions;

FIG. 3B shows the results of a confirmation test for confirming the optimal surface roughness of second contact regions;

FIG. 4 shows the results of diffusion rates of grease areas in an exemplary embodiment of the invention and a comparative example; and

FIG. 5 shows an overall construction of a heat dissipation structure of a vehicular inverter.

### DETAILED DESCRIPTION OF EMBODIMENTS

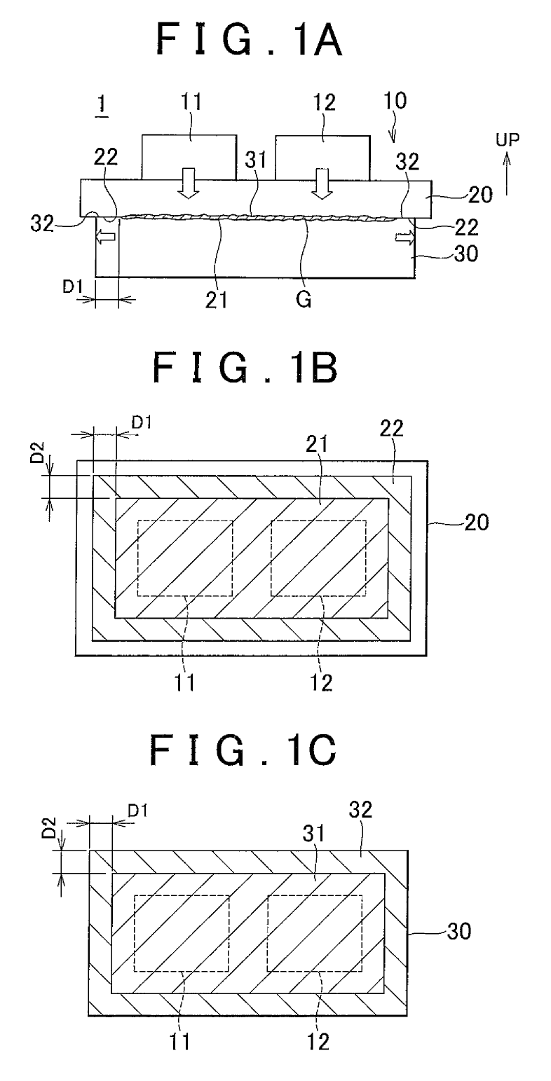

The embodiments regarding a heat dissipation structure of the invention will be described hereinafter with reference to the drawings. FIGS. 1A, 1B, and 1C each show an overall construction of a heat dissipation structure 10 of a vehicular inverter 1 according to the first embodiment of the invention.

The heat dissipation structure 10 shown in FIG. 1A is a heat dissipation structure of a converter portion of the vehicular inverter 1. The heat dissipation structure 10 is equipped with a boost intelligent power module (boost IPM) 11 and a reactor 12 as heating elements. The heating elements radiate heat when the vehicular inverter 1 is in operation. The boost IPM 11 and the reactor 12 are laid on a case (substrate) 20. The case 20 may be bolted to a cooler (heat dissipation member) 30 via thermally conductive grease G containing, for example, base oil such as silicone or the like in a filler. Owing to this basic construction, heat generated by the boost IPM 11 and the reactor 12 is transferred to the cooler 30 in the direction indicated by longitudinal arrows of FIG. 1A.

Further, as shown in FIGS. 1B and 1C, contact surfaces of the case 20 and the cooler 30 have first contact regions 21 and 31 and second contact regions 22 and 32 respectively. When the heat dissipation structure 10 shown in FIG. 1A is established, the first contact region 21 of the case 20 is in contact with the first contact region 31 of the cooler 30, and the second contact region 22 of the case 20 is in contact with the second contact region 32 of the cooler 30.

As shown in FIGS. 1B and 1C, the second contact region 22 surrounds the outer periphery of the first contact region 21, and the second contact region 32 surrounds the outer periphery of the first contact region 31. The boost IPM 11 and the reactor 12 are laid on a face of the case 20 which is opposite to a face of the case 20 that contacts the cooler 30 so that the boost IPM 11 and the reactor 12 are at a position corresponding to the first contact regions 21 and 31. As shown in FIGS. 1B and 1C, the second contact regions 22 and 32 are rectangular regions and the widths D1 and D2 of the region between the outer peripheries of the first contact regions 21 and 31 and the outer peripheries of the second contact regions 22 and 32 are maintained at a minimum of 15 mm.

Furthermore, the surface roughness of the second contact regions 22 and 32 is lower than that of the first contact regions 21 and 31. More preferably, the surface roughness of the first contact regions 21 and 31 have a centerline average roughness Ra equal to or larger than 0.2 μm, and the surface roughness of the second contact regions 22 and 32 have a centerline average roughness Ra equal to or smaller than 0.05 μm.

In the heat dissipation structure 10 thus constructed, heat generated by the boost IPM 11 and the reactor 12 as the heating elements is transferred to the case 20, and conveyed to the cooler 30 via the thermally conductive grease G disposed between the case 20 and the cooler 30.

In this case, the thermally conductive grease G is disposed on the second contact regions 22 and 32, and the surface roughness of the second contact regions 22 and 32 is lower than that of the first contact regions 21 and 31. The thermally conductive grease on the first contact regions 21 and 31 is thereby restrained from flowing. As a result, the thermally conductive grease G on the first contact regions 21 and 31 is unlikely to flow, and an air is unlikely to intrude between the first contact regions 21 and 31.

Furthermore, the second contact regions 22 and 32 surround the first contact regions 21 and 31 respectively. Therefore, an oil component of the thermally conductive grease disposed on the first contact regions 21 and 31 seldom flows toward the second contact regions (in directions indicated by lateral arrows of FIG. 1A) through capillary action.

As a result, the state of the thermally conductive grease G disposed between the first contact regions 21 and 31 does not change even in the course of long-time use. Therefore, heat generated by the boost IPM 11 and the reactor 12 laid on the case 20 is dissipated via the thermally conductive grease G. Thus, the dissipation of heat by the heat dissipation structure 10 is restrained from deteriorating.

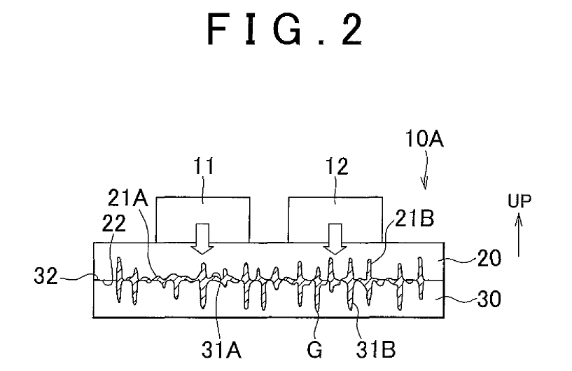

FIG. 2 shows a heat dissipation structure 10A according to the second embodiment of the invention. The heat dissipation structure 10A differs from the heat dissipation structure 10 according to the first embodiment of the invention in first contact regions 21A and 31A of the case 20 and the cooler 30. The other structural details of the second embodiment of the invention, which are identical to those of the first embodiment of the invention, are denoted by the same reference symbols respectively and will not be described in detail below.

As shown in FIG. 2, a plurality of pores 21B and 31B for retaining the grease G are formed in a thickness direction of the case 20 and the cooler 30 in the first contact regions 21A and 31A of the heat dissipation structure 10A according to the second embodiment of the invention. The pores 21B and 31B are formed in the first contact regions 21A and 31A using conventional methods such as, for example, machining, etching, or the like.

As described above, the plurality of pores 21B and 31B are provided in the first contact regions 21A and 31A, on which the thermally conductive grease G is disposed. The thermally conductive grease G on the first contact regions 21A and 31A is thereby trapped by the pores 21B and 31B respectively, and is thus prevented from flowing. Furthermore, as is the case with the first embodiment of the invention, the second contact regions 22 and 32 also surround the first contact regions 21A and 31A. Therefore, the oil component of the thermally conductive grease disposed on the first contact regions seldom flows to the second contact regions through capillary action. As a result, the state of the thermally conductive grease G disposed between the first contact regions 21A and 31A does not change even in the course of long-time use. Therefore, heat generated by the boost IPM 11 and the reactor 12 laid on the case 20 is dissipated via the thermally conductive grease G. Thus, the dissipation of heat by the heat dissipation structure 10 is restrained from deteriorating.

### <Confirmation Test 1>

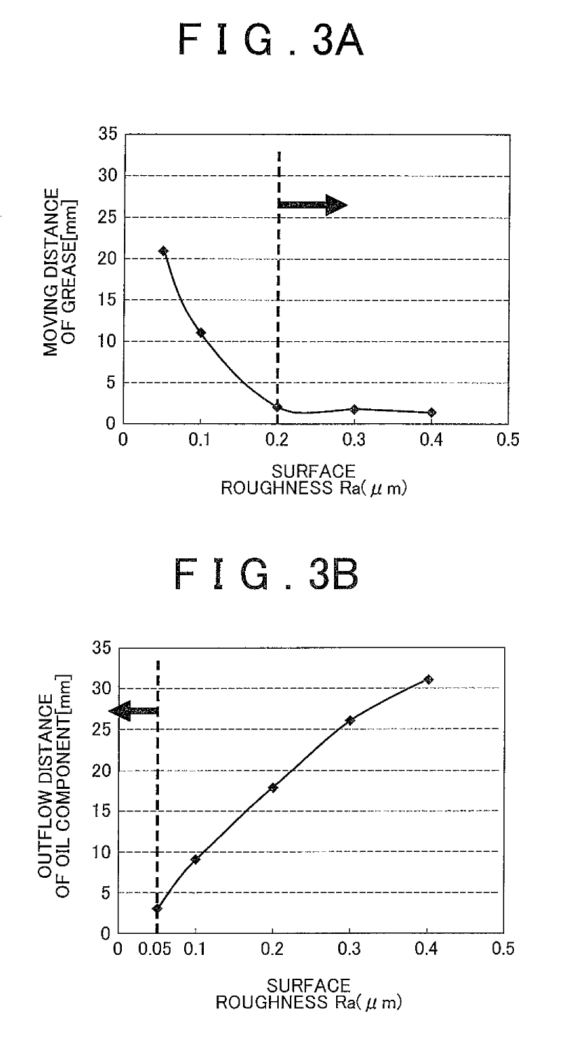

As shown in FIG. 3A, aluminum plates that differ in surface roughness (centerline average roughness Ra) from each other are prepared. Silicone grease as the thermally conductive grease is then disposed between the aluminum plates. A heat cycle test is then conducted in which one cycle of temperature change from a temperature equal to or lower than 0° C. to a temperature in the vicinity of 100° C. is repeated 500 times. After that, a moving distance of the silicone grease is measured. FIG. 3A shows a result of this test. In the following description, it should be noted that the centerline average roughness Ra is measured by a stylus-type surface roughness measuring instrument.

As shown in FIG. 3A, if the centerline average roughness Ra of the aluminum plates is equal to or larger than 0.2 μm, the moving distance of the silicone grease is short. This result shows that it is preferable to set the centerline average roughness Ra of the first contact regions equal to or larger than 0.2 μm.

### <Confirmation Test 2>

As shown in FIG. 3B, aluminum plates that differ in surface roughness (centerline average roughness Ra) from each other are prepared. Silicone grease as the thermally conductive grease and is then disposed between the aluminum plates. A heat cycle test similar to that of test 1 is then conducted. After that, a moving distance of oil contained in the silicone grease is measured. FIG. 3B shows a result of this test.

As shown in FIG. 3B, when the centerline average roughness Ra of the aluminum plates is equal to or smaller than 0.05 μm, the outflow distance of the oil contained in the silicone grease is short. This result shows that it is preferable to set the centerline average roughness Ra of the second contact regions equal to or smaller than 0.05 μm.

### Exemplary Embodiment

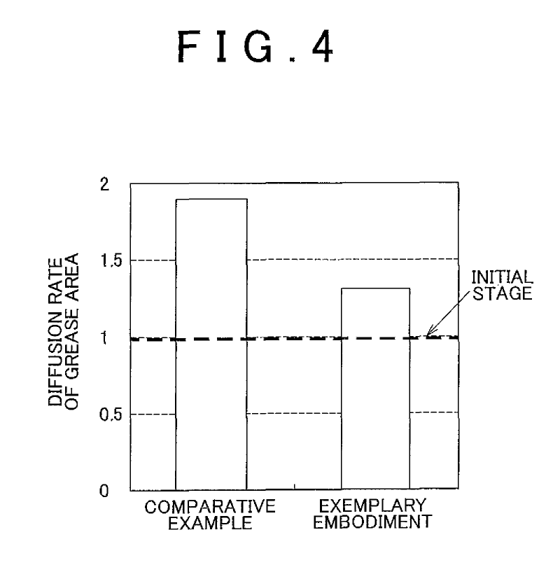

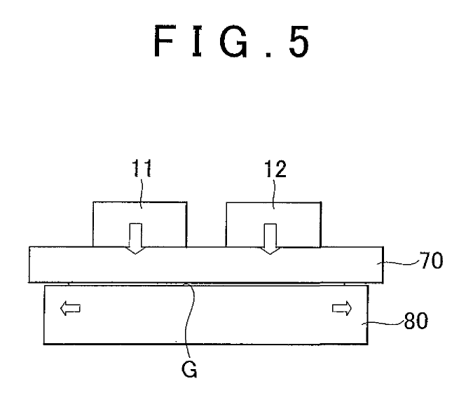

Two aluminum plates are prepared as members representative of the case (substrate) and the cooler (heat dissipation member) according to the first embodiment of the invention. First contact regions having a centerline average roughness Ra of 0.2 μm and second contact regions, which surround the outer periphery of the first contact regions, having a centerline average roughness Ra of 0.05 μm are machined in the contact surfaces of the aluminum plates which are in contact with each other. The same silicone grease as used in the confirmation test 1 is then disposed between these aluminum plates, and a heat cycle test similar that of the confirmation test 1 is conducted. Areas where the silicone grease is disposed are then measured before and after the heat cycle test, and the diffusion rate of the grease area is calculated according to the formula: (diffusion rate of grease area)=(area where grease is disposed after heat cycle test)÷(area where grease is disposed before heat cycle test). FIG. 4 shows a result of this test.

### Comparative Example

A test similar to that of the exemplary embodiment of the invention is conducted. This comparative example differs from the exemplary embodiment of the invention in that the centerline average roughness Ra of the contact surfaces of both aluminum plates is set to 0.2 μm. A diffusion rate is then measured as in the case of the exemplary embodiment of the invention. FIG. 4 shows a result of this test.

### [Result]

In the exemplary embodiment of the invention, the first contact regions and second contact regions, which surround the first contact regions, are formed on the surfaces where the aluminum plates contact each other, the silicone grease is disposed on the first contact regions, and the second contact regions are formed with a lower degree of surface roughness than the first contact regions. Therefore, as shown in FIG. 4, more silicone grease and more oil component are restrained from flowing out in the exemplary embodiment of the invention than in the comparative example.

### [Speculation]

Although the embodiments of the invention have been described above in detail with reference to the drawings, the concrete construction of the invention should not be limited to the described embodiments. Any design change made without departing from the gist of the invention is included in the invention.

For example, in both the first and the second embodiments of the invention, the aforementioned first contact regions and the aforementioned second contact regions are provided on the surface of both the case and the cooler respectively. However, the first contact region and the second contact region may alternatively be provided on only one of the case and the cooler as long as dissipation of heat is ensured.

Further, the thermally conductive grease may be omitted from the second contact regions. Furthermore, although a surface roughness of the second contact regions of the case and the cooler are lower than a surface roughness of the first contact regions in the first embodiment of the invention, a plurality of pores may further be formed in the first contact regions in the thickness direction as described in the second embodiment of the invention.

What is claimed is:

1. A heat dissipation structure comprising:
a heating element;
a substrate on which the heating element is provided; a thermally conductive grease that is provided in a manner such that the substrate is disposed between the heating element and the thermally conductive grease; and
a heat dissipation member that is in contact with the substrate via the thermally conductive grease, wherein
the substrate and the heat dissipation member have contact surfaces that are in contact with each other, and at least one of the contact surfaces has a first contact region on which the thermally conductive grease is disposed, and a second contact region that surrounds the first contact region, and wherein
a surface roughness of the second contact region is lower than a surface roughness of the first contact region.

2. The heat dissipation structure according to claim 1, wherein
the surface roughness of the first contact region has a centerline average roughness equal to or larger than 0.2 μm.

3. The heat dissipation structure according to claim 1, wherein
the surface roughness of the second contact region has a centerline average roughness equal to or smaller than 0.05 μm.

4. The heat dissipation structure according to claim 1, wherein
a plurality of pores is formed in the first contact region in a thickness direction.

5. The heat dissipation structure according to claim 1, wherein
the heating element is provided on a face of the substrate which is opposite to a face of the substrate that contacts the heat dissipation member so that the heating element are at a position corresponding to the first contact region.

6. The heat dissipation structure according to claim 1, wherein
the second contact region has a minimum width of at least 15 mm.

7. A vehicular inverter that incorporates the heat dissipation structure according to claim 1.

8. A heat dissipation structure comprising:
a heating element;
a substrate on which the heating element is provided;
a thermally conductive grease that is provided in a manner such that the substrate is disposed between the heating element and the thermally conductive grease; and
a heat dissipation member that is in contact with the substrate via the thermally conductive grease, wherein
the substrate and the heat dissipation member have contact surfaces that are in contact with each other, and at least one of the contact surfaces has a first contact region on which the thermally conductive grease is disposed and a second contact region that surrounds the first contact region, and wherein
a plurality of pores, in which the thermally conductive grease is retained, is formed in the first contact region in a thickness direction.

9. The heat dissipation structure according to claim 8, wherein
the heating element is provided on a face of the substrate which is opposite to a face of the substrate that contacts the heat dissipation member so that the heating element are at a position corresponding to the first contact region.

10. The heat dissipation structure according to claim 8, wherein
the second contact region has a minimum width of at least 15 mm.

11. A vehicular inverter that incorporates the heat dissipation structure according to claim 8.
